(19) United States
(12) Patent Application Publication
(10) Pub. No.: US 2008/0305619 A1
(43) Pub. Date: Dec. 11, 2008

(54) METHOD OF FORMING GROUP IV SEMICONDUCTOR JUNCTIONS USING LASER PROCESSING

(76) Inventors: Francesco Lemmi, Sunnyvale, CA (US); Andreas Meisel, Redwood City, CA (US); Homer Antoniadis, Mountain View, CA (US)

Correspondence Address: Foley & Lardner LLP, 150 East Gilman Street, Madison, WI, 53701-1497, US

(21) Appl. No.: 12/114,141

(22) Filed: May 2, 2008

Related U.S. Application Data
(60) Provisional application No. 60/915,819, filed on May 3, 2007.

(51) Int. Cl. H01L 21/20; H01L 21/02

(52) U.S. Cl. 438/492; 438/795; 257/E21.002; 257/E21.09

(57) ABSTRACT

A method forming a Group IV semiconductor junction on a substrate is disclosed. The method includes depositing a first set Group IV semiconductor nanoparticles on the substrate. The method also includes applying a first laser at a first laser wavelength, a first fluence, a first pulse duration, a first number of repetitions, and a first repetition rate to the first set Group IV semiconductor nanoparticles to form a first densified film with a first thickness, wherein the first laser wavelength and the first fluence are selected to limit a first depth profile of the first laser to the first thickness. The method further includes depositing a second set Group IV semiconductor nanoparticles on the first densified film. The method also includes applying a second laser at a second laser wavelength, a second fluence, a second pulse duration, a second number of repetitions, and a second repetition rate to the second set Group IV semiconductor nanoparticles to form a second densified film with a second thickness, wherein the second laser wavelength and the second fluence are selected to limit a second depth profile of the second laser to the second thickness.

### CROSS-REFERENCE TO RELATED APPLICATIONS

This application claims priority to U.S. Provisional Patent Application No. 60/915,819 entitled “Method for Fabrication of Photovoltaic Devices From Group IV Nanoparticles Using Laser Processing,” filed May 3, 2007, which is incorporated by reference.

### FIELD OF DISCLOSURE

This disclosure relates to native semiconductor thin films formed from Group IV nanoparticle materials.

### BACKGROUND

The Group IV semiconductor materials enjoy wide acceptance as the materials of choice in a range devices in numerous markets such as communications, computation, and energy. Currently, particular interest is aimed in the art at improvements in semiconductor thin film technologies due to the widely recognized disadvantages of the current chemical vapor deposition (CVD) technologies.

In that regard, with the emergence of nanotechnology, there is growing interest in leveraging the advantages of these new materials in order to produce low-cost devices with designed functionality using high volume manufacturing on nontraditional substrates. It is therefore desirable to leverage the knowledge of Group IV semiconductor materials and at the same time exploit the advantages of Group IV semiconductor nanoparticles for producing novel thin films which may be readily integrated into a number of devices.

One such advantage is that Group IV semiconductor nanoparticle materials offer the potential of high volume, low-cost processing, such as printing, for the ready deposition of a variety of Group IV nanoparticle inks on a range of substrate materials. After printing, a suitable fabrication method of a Group IV semiconductor device, such as a range of optoelectric devices, including photovoltaic devices must be selected that is compatible with the overall goal of high volume processing.

The use of laser processing methods have proven to be useful in the preparation of Group IV semiconductor-based devices, and laser recrystallization of CVD deposited amorphous silicon is well known in the art. An advantage of the use of lasers in the recrystallization of amorphous silicon thin films is that the localized heating of the thin film allows a wider choice of substrates. The use of laser processing in the formation of thin films of deposited nanoparticle materials is gaining interest.

For example, U.S. Pat. No. 7,987,523 [Grigoropoulos, et al.; Ser. No. 10/621,046 filing date Jul. 16, 2003], disclosure is given of producing structures on a substrate by depositing drops of a solution of nanoparticles on a substrate using a droplet generator, at least partially melting the nanoparticles deposited on the substrate using a laser, and allowing the at least partially melted nanoparticles to solidify to form a structure. The examples given are for preparation of formulation and deposition of gold nanoparticles processed using an argon ion laser operating at 488 nm or 514 nm, forming a single thin film thickness of the gold nanoparticles of between about 100 nm to about 250 nm.

The use of a continuous wave solid state YAG laser with emission at 1064 nm to form thin films using silicon nanoparticles has been described [Bet, S.; Kar, A. J. Elec. Mat. 2006 35[5] 993-1004]. Using an aqueous dispersion of 5 nm silicon nanoparticles, the authors dispersed the silicon nanoparticles onto a nickel substrate. Since metal induced crystallization (MIC) using nickel is known to reduce the crystallization temperature of silicon thin films, the authors formed such MIC crystalline thin films, having a thickness of 1-3 microns using laser power in the range of 5-9 W. Cubic crystallites of silicon were observed to form in the film under such conditions. Laser doped thin films were created by adding dopants; either in gaseous or powder form to the silicon nanoparticle film, and activating the dopants using laser processing.

Additionally, in a separate report [Bet, S.; Kar, A. Mat. Sci. Eng. B 2006 130 228-236], the authors also used a continuous wave solid state YAG laser with emission at 1064 nm, but deposited silicon nanoparticles onto plastic substrates. Though it is acknowledged that oxidation of the silicon nanoparticles has an impact on sintering and recrystallization, the 5 nm silicon nanoparticles are nonetheless prepared as aqueous suspensions. In a first stage of laser processing, the laser heating of the cast silicon nanoparticle thin film formed agglomeration of the particles and densification. With further laser heating of the densified thin film caused necking and sintering, and in the last laser annealing step, a coalesced silicon thin film was formed. Depending on the laser annealing conditions, silicon crystallites of between about 3-5 microns and up to 10-12 microns were formed in the laser-coalesced thin film. Thin film and aspects of the formation of thin films using laser processing are discussed in both articles, but the fabrication of working optoelectric devices, such as photovoltaic devices is not described.

In U.S. Patent Application Publication No. 2006/0237719 [Colfer, et al.; Ser. No. 10/533;291 filing date Oct. 30, 2006] disclosure is given for the preparation of electronic components using nanoparticle materials and laser processing thereof. Though note is made of the problem of oxidation of Group IV semiconductor nanoparticles, nonetheless description is given for the preparation of Group IV semiconductor nanoparticles in aqueous dispersions containing about 30% of the surfactant polyethylene glycol (MW 200). In an example of the fabrication of a transistor, liquid dopants are added to the ink formulations, and dopant activation is apparently achieved using laser processing. Though the fabrication of a transistor is disclosed, in such an electrical component the doped layers are arranged essentially orthogonally to the plane of the substrate with very limited area contact between doped layers. The selection of lasers recited reflects matching of the absorbance characteristics of the materials processed in the vertical layers. In contrast, in the fabrication of an optoelectric device, such as a photovoltaic device, the semiconductor thin film layers are layered essentially parallel to the plane of the substrate, where the large area of contact between doped layers and substrate or intrinsic layer requires control of dopant diffusion. In such a device, it is important to control the depth profiling of the fabrication process.

Therefore there is a need in the art for the formation of Group IV semiconductor devices, including a range of optoelectric devices, such as photovoltaic devices, using printable formulations of Group IV semiconductor nanoparticle materials. Such printable formulations are amenable to a variety of printing techniques offering a range of print dimensions from sub-microns to meters. Once deposited on a number of suitable substrates, Group IV nanoparticle thin films may be subsequently processed using laser forming to fabricate continuous Group IV semiconductor thin film layers that are integrated into a variety of single- and multi-junction devices.

### SUMMARY

A method forming a Group IV semiconductor junction on a substrate is disclosed. The method includes depositing a first set of Group IV semiconductor nanoparticles on the substrate. The method also includes directing a first laser beam having a first laser wavelength, a first fluence, a first pulse duration, a first number of repetitions, and a first repetition rate onto the first set of Group IV semiconductor nanoparticles to form a first densified film with a first thickness, wherein the first laser wavelength and the first fluence are selected to limit a first depth profile of the first laser to the first thickness. The method further includes depositing a second set of Group IV semiconductor nanoparticles on the first densified film. The method also includes directing a second laser beam having a second laser wavelength, a second fluence, a second pulse duration, a second number of repetitions, and a second repetition rate onto the second set of Group IV semiconductor nanoparticles to form a second densified film with a second thickness, wherein the second laser wavelength and the second fluence are selected to limit a second depth profile of the second laser to the second thickness.

### BRIEF DESCRIPTION OF THE DRAWINGS

FIG. 1A-F depict a process for fabricating an embodiment of a single junction photoconductive thin film device using Group IV semiconductor nanoparticles and laser processing; and

FIG. 2 depicts pre-processing steps that occur before the formation of a Group IV semiconductor thin film using laser processing.

### DETAILED DESCRIPTION

The fabrication of Group IV semiconductor devices from Group IV semiconductor nanoparticle materials and laser processing is disclosed herein. The Group IV semiconductor nanoparticles are prepared in high quality in inert conditions, and formulated in inert conditions into stable Group IV nanoparticle inks. Single-junction or multi-junction devices can be fabricated on a variety of substrates by sequentially printing a nanoparticle layer and forming a densified Group IV semiconductor thin film from a printed layer using laser processing, and repeating the step to form various embodiments of Group IV semiconductor devices. The laser processing steps take advantage of specific wavelengths of lasers; and hence the penetration depth, as well as the laser fluence, to localize the fabrication to a single deposited layer, avoiding such problems as untoward dopant diffusion thereby.

Regarding the formation of Group IV semiconductor inks, various inks may be formulated from a range of types of Group IV semiconductor nanoparticles; for example 1.) single or mixed elemental composition; including alloys, core/shell structures, doped nanoparticles, and combinations thereof 2.) single or mixed shapes and sizes, and combinations thereof, and 3.) single form of crystallinity or a range or mixture of crystallinity, and combinations thereof. Such inks may be used in the fabrication of a range of optoelectric devices, on a variety of substrates using deposition methods such as, for example, but not limited by, roll coating, slot die coating, gravure printing, flexographic drum printing, and ink jet printing methods, or combinations thereof.

It is desirable to leverage the knowledge of Group IV semiconductor materials and at the same time exploit the advantages of Group IV semiconductor nanoparticles for producing novel thin film devices. The Group IV semiconductor nanoparticles, and the inks produced from them, must have properties that are suitable for producing high-quality Group IV semiconductor devices. Additionally, given the noted reactivity of the particles, care must be taken from the point of synthesis of the Group IV semiconductor nanoparticles to avoid contamination known to be undesirable in semiconductor devices. Though any method of producing Group IV semiconductor nanoparticle materials in an inert environment may be used, gas phase methods for the preparation of Group IV semiconductor nanoparticles are exemplary of methods for producing high quality Group IV semiconductor nanoparticle materials in an inert environment. For example, U.S. patent application Ser. No. 11/155,340 (Kortshagen, et al.; filing date Jun. 17, 2005), describes the preparation of Group IV semiconductor nanoparticles using an RF plasma apparatus, while U.S. patent application Ser. No. 60/878,328 (Kelman, et al.; filing date Dec. 21, 2006) and U.S. patent application Ser. No. 60/901,768 (Kelman, et al.; filing date Feb. 16, 2007) describe the gas phase preparation of doped Group IV semiconductor nanoparticle materials using an RF plasma apparatus. Additionally, U.S. patent application Ser. No. 60/920,471 (Li, et al.; filing date Mar. 27, 2007) describes the use of a laser pyrolysis reactor for preparation of a variety of Group IV semiconductor nanoparticle materials. All of the aforementioned patent applications are incorporated by reference.

After the preparation of targeted Group IV semiconductor nanoparticle materials, the preparation of inks in an inert environment is done. It is contemplated that desirable attributes of inks for use in fabrication of a variety of optoelectric devices, such as photovoltaic devices, include, but are not limited by, prepared from Group IV nanoparticles of semiconductor grade, prepared in dispersions using materials that preserve the quality of the Group IV semiconductor nanoparticle starting materials, formulations that are readily adopted to a variety of printing technologies, and formulations of inks which show batch to-batch consistency. With respect to the preparation of inks that preserve the quality of the Group IV semiconductor nanoparticle materials, it is desirable to avoid any processing that introduces contaminants, such as, but not limited by, metals, oxygen, and carbon, since it is known that such materials may be difficult to process out readily, and are known to introduce trap states into semiconductor devices.

For example, it is known that bulk semiconductor materials, substantially free of oxygen is in the range of about 10¹⁷ to 10¹⁹ oxygen atoms per cubic centimeter of Group IV semiconductor material. In comparison, for example, for semiconductor grade silicon, there are 5.0×10²² silicon atoms per cubic centimeter, while for semiconductor grade germanium there are 4.4×10²² germanium atoms per cubic centimeter. In that regard, oxygen can be no greater than about 2 parts per million to about 200 parts per million as a contaminant in Group IV semiconductor materials. Therefore, one example of a metric of “inert” is having Group IV semiconductor nanoparticle inks disclosed herein be formulated in an environment that provides a suitably low exposure of the nanoparticle starting materials and ink formulations to sources of oxygen, such as but not limited by oxygen; whether gas or dissolved in a liquid, and water; whether vapor or liquid, so that they can be further processed to produce devices that have comparable electrical and photoconductive properties in comparison to devices fabricated from traditional bulk Group IV semiconductor materials.

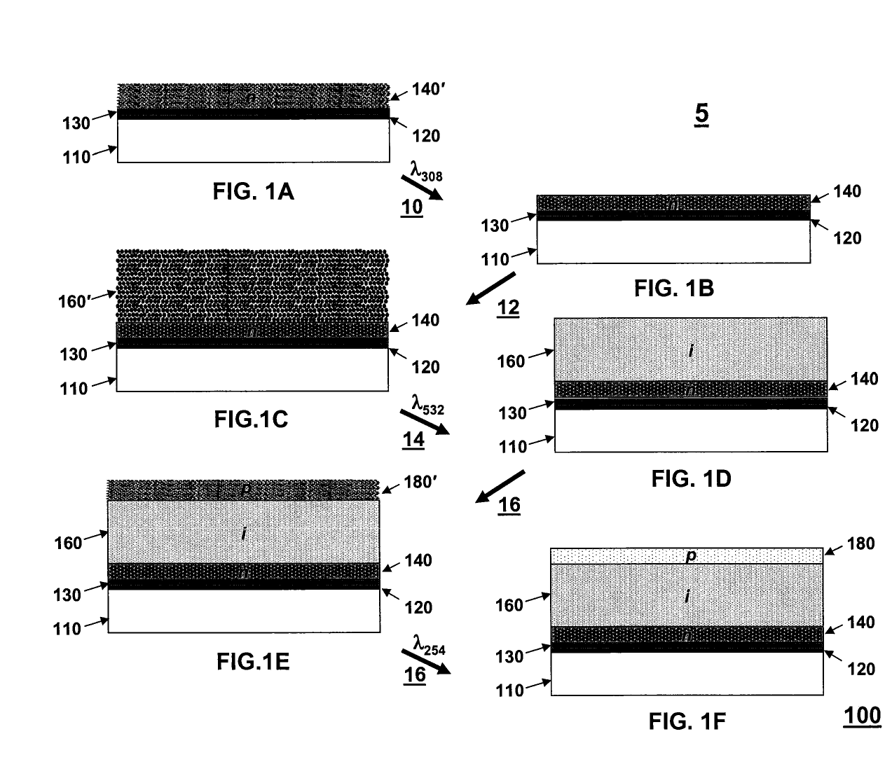

Once formulated as a printable composition, the Group IV semiconductor nanoparticles can be deposited on a number of substrates using a variety of printing technologies, as previously mentioned. An embodiment of a process is depicted in FIG. 1A-F for process 5, having process steps 10-18 for the formation of a single junction p-i-n device 100 of FIG. 1F.

FIG. 1A depicts a porous compact 140′ that is deposited using Group IV semiconductor nanoparticles on substrate 110, upon which a first electrode, 130, and optionally an insulating layer 120 between the substrate 110 and electrode 130 are deposited is shown. Substrate materials may be selected from silicon dioxide-based substrates, such as, but are not limited by, quartz, and glasses, such as soda lime and borosilicate glasses. Native substrates are another class of substrates for use in the preparation of a range of optoelectric devices. The native Group IV semiconductor substrates contemplated for use with Group IV semiconductor nanoparticles include crystalline silicon wafers of a variety of orientations. For example, in some semiconductor device embodiments, wafers of silicon (100) are contemplated for use, while in other embodiments, wafers of silicon (111) are contemplated for use, and in still other embodiments, wafers of silicon (110) are contemplated for use. Such crystalline substrate wafers may be doped with p-type dopants for example, such as boron, gallium, and aluminum.

Alternatively, they may be doped with n-type dopants, for example such as arsenic, phosphorous, and antimony. If the crystalline silicon substrates are doped, the level of doping would ensure a bulk resistivity of between about 0.1 ohm·cm to about 10 ohm·cm. Additional native silicon substrates contemplated include silicon materials deposited on substrates, such as polycrystalline silicon deposited on a variety of substrates, in processes such as, for example PECVD, laser crystallization, or SSP processes. In addition to silicon, such substrates could also be made of silicon and germanium and combinations of silicon and germanium. For the fabrication of other embodiments of semiconductor devices, flexible stainless steel sheet is the substrate of choice, while for the fabrication of still other embodiments of semiconductor devices, the substrate may be selected from heat-durable polymers, such as polyimides and aromatic fluorene-containing polyarylates, which are examples of polymers having glass transition temperatures above about 300° C.

In FIG. 1A, the first electrode 130 is selected from conductive materials, such as, for example, aluminum, molybdenum, silver, chromium, titanium, nickel, and platinum. For various embodiments of photoconductive devices contemplated, the first electrode 130 is between about 10 nm to about 1000 nm in thickness. Optionally, an insulating layer 120 may be deposited on the substrate 110 before the first electrode 130 is deposited. Such an optional layer is useful when the substrate is a dielectric substrate, since it protects the subsequently fabricated Group IV semiconductor thin films from contaminants that may diffuse from the substrate into the Group IV semiconductor thin film during fabrication. When using a conductive substrate, the insulating layer 120 not only protects Group IV semiconductor thin films from contaminants that may diffuse from the substrate, but is required to prevent shorting. Additionally, an insulating layer 120 may be used to planarize an uneven surface of a substrate. Finally, the insulating layer may be thermally insulating to protect the substrate from stress during some types of processing, for example, when using lasers. The insulating layer 120 is selected from dielectric materials such as, for example, but not limited by, silicon nitride, alumina, and silicon oxides. Additionally, layer 120 may act as a diffusion barrier to prevent the accidental doping of the active layers. For various embodiments of photoconductive devices contemplated the insulating layer 120 is about 50 nm to about 100 nm in thickness.

Regarding fabrication of a single junction device 100 of FIG. 1F using Group IV semiconductor, for the process step 10 of FIG. 1A, the porous compact 140′, shown as a deposited thin film of n-type doped Group IV nanoparticles, is fabricated to an n-type semiconductor thin film 140 of FIG. 1B using laser processing. As previously mentioned, though the preparation of the Group IV semiconductor nanoparticles and nanoparticle inks is done in an inert environment, the printing of the porous compact and subsequent laser processing may be done in a variety of process environments, as will be discussed in more detail subsequently. Porous compact n-type layer 140′ of FIG. 1B may be between about 50 nm to about 400 nm, and after laser processing an n-type semiconductor thin film 140 of FIG. 1B of between about 25 nm to about 200 nm is fabricated.

In terms of general considerations for the laser processing of a Group IV nanoparticle porous compact, laser processing variables, include the wavelength of laser emission to control penetration depth, the energy density, or fluence of the laser, and the duration and number of repetitions of laser pulses, when using pulsed laser processing. The selection of these laser processing variables is related to device attributes, such as the thermal mass of the layer on which the film being processed has been deposited, the thickness of the film being processed, and the contact area of the film being processed to other material layers.

### EXAMPLE 1

In that regard, for the fabrication of a semiconductor thin film, such as the n-type thin film 140 of FIG. 1B from n-type porous compact 140′ of FIG. 1A, in consideration of the range of film thicknesses, though a wavelength of 308 nm is indicated for step 10, the use of lasers having emission wavelengths in the UV range is indicated for processing a porous compact having a thickness between about 50 nm to about 400 nm. For example, there are a number of excimer lasers available in the far to near UV wavelength range of about 193 nm to about 361 nm. Given the wide selection of substrates possible, and the variation of the thermal masses represented in the possible substrates, using lasers in the far to near UV wavelength range with a fluence of between about 5-300 mJ/cm², and with between about 1 to about 1000 repetitions for a laser with a repetition rate of between about 10 HZ to about 100 Hz (should we increase this to kHz?), having a pulse duration of between about 1 ns to about 100 ns is indicated for processing a porous compact film of between about 50 nm to about 400 nm to a semiconductor thin film of between about 25 nm to about 200 nm.

After the fabrication of n-type thin film 140 of FIG. 1B, in process step 12, a layer of intrinsic Group IV semiconductor nanoparticles is printed on n-type thin film 140 to form intrinsic porous compact layer 160′ of FIG. 1C. The intrinsic porous compact layer 160′ of FIG. 1C may be between about 400 nm to about 6 micron, and after laser processing an intrinsic semiconductor thin film 160 of FIG. 1D of between about 200 nm to about 3 micron is fabricated.

For the fabrication of a semiconductor thin film, such as the intrinsic thin film 160 of FIG. 1D from intrinsic porous compact 160′ of FIG. 1C, in consideration of the range of film thicknesses, though a wavelength of 532 nm is given for step 14, the use of lasers with emission wavelengths in the visible through infrared (IR) range is indicated for processing a porous compact having a thickness between about 400 nm to about 6 micron. The choice of lasers with emission in the visible and IR range is suitable for use for the selective penetration of such porous compact film thicknesses. For example, but not limited by, solid state YAG lasers have emissions in the visible and IR range, and are therefore suitable for the processing of porous compact thin films in the range of between about 400 nm to about 6 micron. The selection of the wavelength and fluence to control the depth profiling of the laser fabrication process is important, since the intrinsic porous compact layer is cast upon an n-type semiconductor layer. Therefore, in such thin film layer stacks, where there is significant area of contact between layers, the use of lasers to control the depth profiling by the selection of wavelength and fluence during the fabrication of a targeted thin film is essential for ensuring final device performance. In this example, controlling the depth profiling of the fabrication process for the intrinsic layer is important so the n-type layer is not heated, causing dopant diffusion from the n-type layer to occur (could maybe be shortened since we repeat the key statements?)

In that regard, it is contemplated that in order to effectively fabricate the intrinsic thin film 160 of FIG. 1D of between about 200 nm to about 3 microns from intrinsic porous compact 160′ of FIG. 1C of between about 400 nm to about 6 micron using a laser with an emission at 532 nm, a range with a fluence of between about 10-150 mJ/cm², and with between about 1 to about 1000 repetitions with a repetition rate of between about 10 HzZ to about 100 Hz, having a pulse duration of between about 1 ns to about 100 ns is indicated. For the laser processing of intrinsic thin film 160 of FIG. 1D of between about 200 nm to about 3 microns from intrinsic porous compact 160′ of FIG. 1C of between about 400 nm to about 6 micron using a laser with an emission at 1064 nm, a range with a fluence of between about 4 mJ/cm² to about 2000 mJ/cm² , and with between about 1 to about 100 repetitions with a repetition rate of between about 10 Hz to about 100 Hz, having a pulse duration of between about 1 ns to about 100 ns is indicated.

Finally, after the fabrication of intrinsic thin film 160 of FIG. 1D, a p-type doped Group IV semiconductor porous compact 180′ of FIG. 1E is printed on intrinsic thin film 160, as depicted in process step 16. The p-type porous compact 160′ of FIG. 1E may be between about 40 nm to about 400 nm, and after laser processing a p-type semiconductor thin film 180 of FIG. 1F of between about 20 nm to about 200 nm is fabricated. For the fabrication of a semiconductor thin film, such as the intrinsic thin film 180 of FIG. 1F from a p-type porous compact film 180′ of FIG. 1E, in consideration of the range of film thicknesses, though a wavelength of 254 nm is given for step 18, the use of lasers with emission wavelengths in the UV wavelength range is indicated for processing a porous compact having a thickness between about 40 nm to about 400 nm. As given for the previous example of the processing of the n-type thin film 140 of FIG. 1B, excimer lasers available in the far to near UV wavelength range of about 193 nm to about 361 nm, as well as Nd:YAG lasers having harmonics in the UV region, are suitable for use in fabrication of thin film having a thickness between about 40 nm to about 400 nm. Since the p-type layer is a thin layer in comparison to the intrinsic layer 160, the thermal mass of the intrinsic layer must be taken into account, as must laser processing conditions that prevent excessive heating of the p-doped layer, and hence dopant diffusion into the intrinsic layer. For the p-type porous compact film 180′ of thickness between about 40 nm to about 400 nm suitable laser processing condition for forming a p-type thin film layer 180 of FIG. 1F are the use of lasers in the far to near UV wavelength range with a fluence of between about 5-500 mJ/cm², and with between about 1 to about 1000 repetitions with a repetition rate of between about 10 Hz to about 100 Hz, having a pulse duration of between about 1 ns to about 100 ns is indicated for processing a porous compact film of between about 100 nm to about 400 nm to a semiconductor thin film of between about 50 nm to about 200 nm.

Finally, though not shown in the figures sequence of FIG. 1A-F, after the processing to form the p-i-n junction is complete, a transparent conductive oxide (TCO) is deposited on the p-type thin film layer 180. This not only provides a second electrode, but moreover allows a photo flux to penetrate to the photoconductive layers. Materials useful for the TCO layer include, but are not limited by indium tin oxide (ITO), tin oxide (TO), and zinc oxide (ZnO). For various embodiments of photoconductive devices contemplated, the TCO layer is from about 100 nm to about 200 nm in thickness. Alternatively, other materials contemplated for use in the TCO layer include, for example, but not limited by, conductive polymers in the family of 3,4 ethylenedioxythiophene conducting polymers, polyanilines, as well as conducting materials such as fullerenes. Such materials may be prepared as liquid suspensions, and as such may be readily applied and cured.

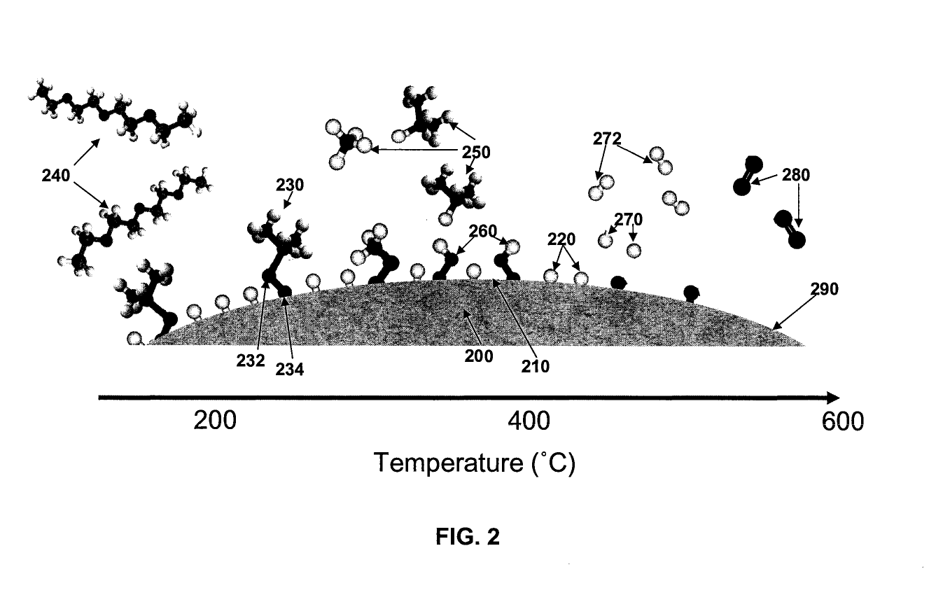

Prior to the laser processing of the deposited Group IV semiconductor porous compact, preprocessing steps are done to sufficiently remove materials that may otherwise be undesirable in the formed Group IV semiconductor device. For example, in FIG. 2, the processing of a variety of constituents in a Group IV semiconductor ink formulation is shown as a function of temperature. The embodiment of the Group IV semiconductor nanoparticle ink formulation depicted in FIG. 2 utilizes a first step of reacting the Group IV semiconductor nanoparticle material with a bulky t-butoxy capping group, and then is dispersed in diethylene glycol diethyl ether (DEGDE). This t-butoxy/DEGDE ink formulation, as well as other embodiments of Group IV semiconductor nanoparticle inks, has been described in U.S. patent application Ser. No. 60/915,817 (Rogojina, et al.; filing date May 3, 2007), and is incorporated by reference.

FIG. 2 depicts a Group IV nanoparticle 200, for example a silicon nanoparticle, having a nanoparticle surface 210, which surface has covalently bound hydrogen groups 220, and bulky t-butoxy groups 230. At temperatures just below 200° C., the vehicle in the formulation, shown as diethylene glycol diethyl ether (DEGDE) 240, which has a boiling point of about 189° C., is depicted as volatizing away from the nanoparticle. At between about 350° C. to about 400° C., the thermal decomposition of the t-butoxy group is initiated with the volatilization of hydrocarbon fragments group 250, leaving behind Si—OH surface groups 260. At 550° C. to about 600° C., hydrogen groups 220 are desorbed, and are volatilized as hydrogen 272. At above 800° C., the evolution of SiO 280 occurs, and at that process temperature, the surface of the Group IV semiconductor particle has essentially no non-native species.

For example, before laser processing, some embodiments of preprocessing steps may involve the use of thermal processing at between about 100° C. to about 400° C. for about 1 minute to about one hour, in an inert environment, for example, such as in the presence of an inert gas, such as a noble gas, nitrogen, or mixtures thereof. Additionally, to create a reducing atmosphere, up to 20% by volume of hydrogen may be mixed with the noble gas, or nitrogen, or mixtures thereof. In other embodiments of thermal preprocessing steps, the preprocessing may be done in vacuo. In still other embodiments of preprocessing steps, laser processing may be used, where the fluence is adjusted according to the heating of the film required to successfully affect the preprocessing step.

### EXAMPLE 2

In this example, a Group IV semiconductor printed porous compact was fabricated using laser processing. Silicon nanoparticles of about 8 nm prepared as a 20 mg/ml formulation of t-butoxy capped particles in DEGDE. On a clean 1″×1″ quartz substrate 110, coated with molybdenum layer 130 of about 100 nm a first layer of silicon nanoparticles of about 450 nm in thickness was printed in inert nitrogen atmosphere using inkjet printing. This first printed porous compact layer was heated at 200° C. in nitrogen atmosphere for 5 minutes. Under these conditions, excess solvent was driven off, and the film was more mechanically stable. A second porous compact layer was printed and preconditioned as per the first layer. The printed layers were then subjected to heating at 375° C. under low pressure (4 torr) nitrogen flow for 20 minutes and cooling down in the same atmosphere for 60 minutes. After the printing and preconditioning steps were complete, a portion of the film shown was processed with a solid state Q-switched Nd:YAG laser with emission at 532 nm, having a 6 ns pulse duration and a repetition rate of 20 Hz, with a fluence of about 50 mJ/cm², using 1000 pulses. The resulting densified silicon thin film formed is about 270 nm in thickness. When observed in a set of scanning tunneling microscopy (SEM) images, the densified film was observed with a substantially grainier in appearance (that is, densified) than when compared to a control area on the same substrate, in which no laser processing was done.

While principles of the disclosed formation of Group IV semiconductor devices from the laser processing of deposited Group IV semiconductor nanoparticle thin films have been described in connection with specific embodiments, it should be understood clearly that these descriptions are made only by way of example and are not intended to limit the scope of what is disclosed. For example, in the figures sequence of FIG. 1A-F, the printing of Group IV semiconductor porous compact thin films and laser processing of such films to fabricate a p-i-n junction device is given. However, as one of ordinary skill in the art is apprised, what is detailed in the given example is readily applicable to other device designs known in the art, such as p-n junction device, and a variety of multi-junction devices.

In that regard, what has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

What is claimed is:

1. A method forming a Group IV semiconductor junction on a substrate, comprising:
depositing a first set of Group IV semiconductor nanoparticles on the substrate;
directing a first laser beam having a first laser wavelength, a first fluence, a first pulse duration, a first number of repetitions, and a first repetition rate onto the first set of Group IV semiconductor nanoparticles to form a first densified film with a first thickness, wherein the first laser wavelength and the first fluence are selected to limit a first depth profile of the first laser to the first thickness;
depositing a second set of Group IV semiconductor nanoparticles on the first densified film;
directing a second laser beam having a second laser wavelength, a second fluence, a second pulse duration, a second number of repetitions, and a second repetition rate onto the second set of Group IV semiconductor nanoparticles to form a second densified film with a second thickness, wherein the second laser wavelength and the second fluence are selected to limit a second depth profile of the second laser to the second thickness.

2. The method of claim 1, wherein the substrate is one of a silicon substrate, a silicon dioxide substrate, a glass substrate, a stainless steel substrate, or a heat durable polymer substrate.

3. The method of claim 2, wherein the silicon substrate is one of n-type or p-type.

4. The method of claim 1, wherein the first set of Group IV semiconductor nanoparticles and the second set of Group IV semiconductor nanoparticles are n-type.

5. The method of claim 1, wherein the first set of Group IV semiconductor nanoparticles and the second set of Group IV semiconductor nanoparticles are p-type.

6. The method of claim 1, wherein the first thickness and the second thickness are from about 25 nm to about 200 nm.

7. The method of claim 1, wherein the first laser wavelength and the second laser wavelength are from about 193 nm to about 1064 nm.

8. The method of claim 1, wherein the first fluence and the second fluence are from about 4 mJ/cm³ to about 2000 mJ/cm³.

9. The method of claim 1, wherein the first repetition rate and the second repetition rate are from about 10 Hz to about 150 Hz.

10. The method of claim 1, wherein the first pulse duration and the second pulse duration are from about 1 ns to about 100 ns.

11. The method of claim 1, wherein the first number of repetitions and the second number of repetitions are from about 1 to about 1000.

12. A method forming a Group IV semiconductor junction on a substrate, comprising:
depositing a first metal layer on the substrate;
depositing a first set of Group IV semiconductor nanoparticles on the first metal layer;
directing a first laser beam having a first laser wavelength, a first fluence, a first pulse duration, a first number of repetitions, and a first repetition rate onto the first set of Group IV semiconductor nanoparticles to form a first densified film with a first thickness, wherein the first laser wavelength and the first fluence are selected to limit a first depth profile of the first laser to the first thickness;
depositing a second set of Group IV semiconductor nanoparticles on the first densified film;
directing a second laser beam having a second laser wavelength, a second fluence, a second pulse duration, a second number of repetitions, and a second repetition rate onto the second set of Group IV semiconductor nanoparticles to form a second densified film with a second thickness, wherein the second laser wavelength and the second fluence are selected to limit a second depth profile of the second laser to the second thickness;
depositing a third set of Group IV semiconductor nanoparticles on the second densified film;
directing a third laser beam having a third laser wavelength, a third fluence, a third pulse duration, a third number of repetitions, and a third repetition rate onto the third set of Group IV semiconductor nanoparticles to form a third densified film with a third thickness, wherein the third laser wavelength and the third fluence are selected to limit a third depth profile of the third laser to the third thickness;
depositing a transparent conductive oxide on the third densified film.

13. The method of claim 12, wherein the substrate is one of a silicon substrate, a silicon dioxide substrate, a glass substrate, a stainless steel substrate, or a heat durable polymer substrate.

14. The method of claim 12, wherein the first densified film is p-type, the second densified film is intrinsic, and the third densified film is n-type.

15. The method of claim 12, wherein the first densified film is n-type, the second densified film is intrinsic, and the third densified film is p-type.

16. The method of claim 12, wherein the first thickness, the second thickness, and the third thickness are from about 25 nm to about 200 nm.

17. The method of claim 12, wherein the first laser wavelength, the second laser wavelength, and the third laser wavelength are from about 193 nm to about 1064 nm.

18. The method of claim 12, wherein the first fluence, the second fluence, and the third fluence are from about 4 mJ/cm³ to about 2000 mJ/cm³.

19. The method of claim 12, wherein the first repetition rate, the second repetition rate, and the third repetition rate are from about 10 Hz to about 150 Hz.

20. The method of claim 12, wherein the first pulse duration, the second pulse duration, and the third pulse duration are from about 1 ns to about 100 ns.

21. The method of claim 12, wherein the first number of repetitions, the second number of repetitions, and the third number of repetitions are from about 1 to about 1000.
